(19) United States
(12) Patent Application Publication
(10) Pub. No.: US 2011/0254566 A1
(43) Pub. Date: Oct. 20, 2011

(54) METHOD FOR MONITORING A LINEAR GUIDE

(75) Inventors: Stefan Gluck, Schweinfurt (DE); Frank Benkert, Waigolshausen (DE)

(73) Assignee: SCHAEFFLER TECHNOLOGIES GMBH & CO. KG, Herzogenaurach (DE)

(21) Appl. No.: 13/088,501

(22) Filed: Apr. 18, 2011

(30) Foreign Application Priority Data
Apr. 16, 2010 (DE) 102010015208.0

(51) Int. Cl. G01R 27/28

(52) U.S. Cl. 324/617

(57) ABSTRACT

A method for monitoring a linear guide with a carriage that can be displaced along a rail on a rolling contact formed from roller bodies rolling on running tracks using a sensor device for detecting a damage state of the rolling contact is provided. In order to provide a simple damage monitoring that can also be carried out for small computational units in short times and with very economical sensor devices, using the sensor device, an oscillation time signal is detected, an envelope curve demodulation of the oscillation time signal is carried out from the oscillation time signal, and a resulting magnitude is determined according to a constant-component determination as a characteristic value that increases with the damage state, and a damage state is recognized when the characteristic value exceeds a specified threshold value.

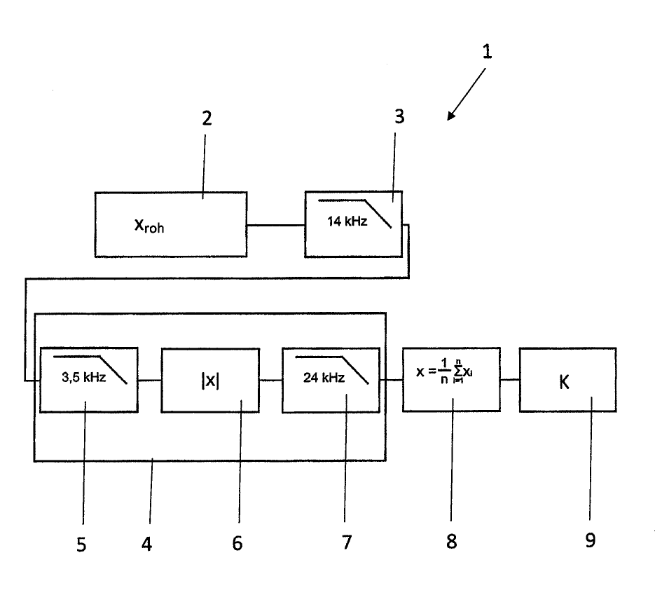

### CROSS-REFERENCE TO RELATED APPLICATIONS

This application claims the benefit of German Patent Application No. 102010015208.0, filed Apr. 16, 2010, which is incorporated herein by reference as if fully set forth.

### FIELD OF THE INVENTION

A method for monitoring a linear guide with a carriage that can be displaced along a rail on a rolling contact formed from roller bodies rolling on running tracks with a sensor device for detecting a damage state of the rolling contact.

### BACKGROUND

Linear guides are used for guiding a carriage along a rail, for example, a profiled rail. For the construction of the guide contact between the rail and the carriage, sliding and rolling contacts are used. Rolling contacts are especially preferred due to the conversion of a sliding friction into a rolling friction. Here, roller bodies are arranged either stationary or recirculating between the profiled rail and the carriage. For example, from DE 41 40 042 A1, recirculating roller units for a linear guide are known. Linear guides are used, in particular, in machine tools, wherein their rolling contact is exposed to strong loading between the roller bodies and the associated running tracks, wherein this loading could result in damage, such as pitting, flaking, and the like, which—if not recognized in due time—could lead to the failure of the linear guide and thus failure of the machine tool with this guide.

From DE 11 2005 002 077 T5, relating to monitoring devices of rotating bearings, a state detection device for linear guides is known that determines, on the basis of a detection of elastically occurring oscillation waves, several parameters that are referenced for the assessment of damage to the linear guide. Due to the complexity of the algorithmic calculation and evaluation processes, for the real-time use of the determined parameters, the state detection device must draw on relatively large computational units, such as microcomputers with microprocessors that are intensive in terms of cost and installation space. Furthermore, for the use of an evaluation of wide and especially high frequency bands in the range of greater than 100 kHz typical for this type of state detection device, a sensor for the detection of acoustic emissions is needed that is complicated and accordingly expensive.

### SUMMARY

The object of the invention is the advantageous refinement of a method for monitoring a damage state of the rolling contact between the roller bodies and their running tracks of a linear guide, in particular, in front of the background of a simple and economical realization of the method using simple components.

This objective is met by a method for monitoring a linear guide with a carriage that can be displaced along a rail via a rolling contact formed from roller bodies rolling on running tracks with a sensor device for detecting a damage state of the rolling contact, wherein, by use of the sensor device, an oscillation time signal is detected, an envelope curve demodulation of the oscillation time signal is carried out from the oscillation time signal, and a resulting magnitude is determined according to a constant-component determination as a characteristic value that increases with the damage state and a damage state is recognized when the characteristic value exceeds a specified threshold value.

By use of the proposed method, all forms of linear guides with lubricated rolling contact, in particular, linear guides constructed as recirculating ball units, can be monitored for a damage state of the rolling contact. For the structural construction of linear guides, reference is made to known embodiments as disclosed, for example, in DE 11 2005 002 077 T5 and DE 41 40 042 A1.

Measures when the specified threshold value is exceeded can be a single-stage or multi-stage warning or alarm signal that could be output for the operating or service personnel. As the last stage of a multi-stage warning signal, for preventing damage to the linear drive, the linear guide could be stopped, in that, for example, a drive, such as an electric motor or the like of this guide, for example, of the carriage that can be displaced in a linear fashion on the profiled rail, is included in a control routine of the determination, detection, and evaluation of the signal time profile. The specified threshold value could have a single-stage or multi-stage construction and could be adapted, for example, to the corresponding embodiment of the linear guide with its specific oscillation and acoustic developments in the undamaged and damaged state.

According to the inventive concept, for limiting the frequency band and thus the data traffic to be processed, limiting can be performed before the envelope curve demodulation by a low-pass filter. Here it has been shown surprisingly that, under the use of the proposed method, frequency bands can be used that were previously blanked out in linear guides as non-selective regions for damage of the rolling contact. For example, according to the inventive concept, frequency ranges are provided that limit a bandwidth of the oscillation time signal to 16 kHz, advantageously 14 kHz. Through the use of such small frequency ranges, sensors, for example, piezoelectric sensors can be used for detecting the oscillation time signals, wherein these sensors are available economically and optionally can be miniaturized sufficiently, for example, through use of microsystem technology. Therefore, through the limitation to frequency ranges less than 16 kHz, the signal detection, for one, and the sensor device, for another, are significantly simplified.

According to one advantageous embodiment, the envelope curve modulation can be performed in a simple way by means of an absolute value determination, with low-pass filters being connected upstream and downstream of this determination. In this way, a further limitation of the frequency range to limiting frequencies less than 5 kHz, advantageously 3.5 kHz can be performed by the low-pass filter connected upstream. The low-pass filter connected downstream can have a blocking effect for limiting frequencies essentially greater than 24 kHz. The magnitude obtained from the envelope curve demodulation could be already used, in principle, as a characteristic value for damage of the rolling contact. It has been shown, however, that this magnitude is relatively unreliable, for example, due to external oscillations that cannot be eliminated by the upstream filtering processes, because they lie in the low frequency range to be observed and to be evaluated. Therefore, according to the inventive concept, after the envelope curve demodulation, this magnitude is subjected to an additional procedure for the determination of the constant component of the magnitude that eliminates the mentioned external oscillations to a sufficient extent, so that the magnitude provided after the determination of the constant component is provided as a characteristic value with sufficient accuracy.

The low-pass filters preferably involve a simple filtering, for example, by a Bessel filter that can be represented in analog or digital and can preferably be of high order, for example, fifth order, so that the construction of the sensor device can be realized easily and by a simple microprocessor.

It has further proven advantageous when the oscillation time signal is detected under defined measurement conditions for comparability of the detected oscillation time signal with oscillation time signals detected under reference conditions. In this way, disruptive influences occurring in this frequency range, for example, artifacts and the like that are typical for the linear guide, can be eliminated in advance. Such disruptive influences can be taken into account, for example, in the threshold value. In the simplest case, this could represent a parameter averaged across the frequency range or could be determined from a set of frequency-dependent parameters. According to the inventive concept, defined measurement conditions are achieved in that the oscillation time signals are detected during at least one measurement travel of the carriage at a known velocity and known load. Here, a constant observance of the velocity across the path of the carriage is preferably provided along the profiled rail; changing velocities, however, could likewise be used for achieving special measurement effects, wherein the velocity profile is specified in a way that can be reproduced and the effective values calculated from this profile supply characteristic values that are compared with threshold values that are fixed taking as a basis the same velocity profiles. A measurement travel of the carriage can here be performed within a short time span, for example, between two working passes of the linear guide integrated into one machine tool, with this time span equaling, for example, less than 3 seconds and advantageously lying in the range of one second.

The arrangement of the sensor device or the sensor of the sensor device, for example, a piezoelectric sensor, advantageously takes place in the carriage that can be displaced relative to the profiled rail. The sensor device could already contain a required evaluation unit and a device for the output of an alarm or could transmit corresponding raw data, partially or completely prepared data, for example, by a connection cable or wirelessly to a stationary evaluation unit. With respect to the movement plane of the carriage and its transverse movement, the sensor is preferably arranged normal, that is, essentially perpendicular to this with its measurement axis or geometric axis. Alternatively, the sensor could be housed as fixed with respect to these axes perpendicular or parallel to the transverse movement outside or in the movement plane.

### BRIEF DESCRIPTION OF THE DRAWINGS

The invention will be explained in detail with reference to the embodiment shown in the sole FIGURE. This shows a block circuit diagram of a method for determining a characteristic value indicating a damage state of a rolling contact of a linear guide.

### DETAILED DESCRIPTION OF THE PREFERRED EMBODIMENTS

The sole FIGURE shows the block circuit diagram 1 for carrying out a method for checking the damage state of a rolling contact of a linear guide between roller bodies and the associated running tracks of these bodies. In block 2, over a time period of one measurement travel of the carriage, the oscillation time signals xᵣₒₕ of the sensor device, for example, the measurement signals of a piezoelectric sensor that is arranged perpendicular to the movement plane of the carriage are read in a data capture device, for example, a volatile or non-volatile memory present in or allocated to a microprocessor. The data advantageously provided from the sensor as analog data and allocated to the oscillations that occur during the measurement travel is here digitized in advance, for example, by means of an A/D converter. In block 3, the digitized data is low-pass filtered by a filter unit, in that, for example, frequencies above 14 kHz are cut. A corresponding digitally operating filter unit in the form of a low-pass filter could be, for example, a Bessel filter of fifth order, a Butterworth filter or the like. Alternatively, the analog data could be filtered by a discrete low-pass filter constructed from hardware components. Here, the data could be further processed in analog or digitized at this point.

The blocks 5, 6, 7 combined in the block 4 form the envelope curve demodulation. Here, in block 5 a low-pass filter is connected upstream of the absolute value determination in block 6, with this filter being constructed, for example, as a Bessel filter of fifth order and having a limit frequency of 3.5 kHz. The absolute value determination |x| following in block 6 determines the absolute value of the oscillation time signals xᵣₒₕ filtered in blocks 3 and 5 and then low-pass filtered in block 7 at a frequency of 24 kHz. For eliminating still existing external oscillations that lie in the frequency range of the oscillation time signals to be detected for determining damage of the rolling contact and thus cannot be filtered out, in block 8 a determination of the constant voltage component is performed, so that individual peak signals of the external oscillations are damped. The constant component is determined with reference to the relationship

$$x = \frac{1}{n} {\sum }_{i = 1}^{n} {x}_{i}$$

The constant components could be provided as discrete magnitudes x determined at a detection rate or could be represented as an integral over the time of one measurement travel and could be mapped in block 9 as characteristic value K that is normalized, for example, to a reference magnitude or is processed in some other way and corresponds to a magnitude for the frequency band being used. Observations have shown that the characteristic value K increases with increasing damage to the rolling contact, so that in block 9 or a subsequent block, a comparison with a threshold value could be performed that marks a still sufficient quality of the state of the rolling contact. If the characteristic value exceeds the threshold value, in the same routine or in another routine, measures are initiated for the output of an alarm to the operating or service personnel, for example, an acoustic and/or visual warning signal, for informing a control room, or the like.

1. A method for monitoring a linear guide with a carriage that can be displaced along a rail on a rolling contact formed from roller bodies rolling on running tracks having a sensor device for detecting a damage state of the rolling contact, the method comprising detecting an oscillation time signal using the sensor device, carrying out an envelope curve demodulation of the oscillation time signal from the oscillation time signal, and determining a resulting magnitude according to a constant-component determination as a characteristic value increasing with a damage state, and recognizing a damage state when the characteristic value exceeds a specified threshold value.

2. The method according to claim 1, further comprising limiting a bandwidth of the oscillation time signal to 16 kHz using a low-pass filter before the envelope curve demodulation.

3. The method according to claim 1, further comprising performing the envelope curve demodulation using an absolute value determination, with a low-pass filter being connected upstream and downstream of this determination.

4. The method according to claim 3, wherein the low-pass filter connected upstream has a limiting frequency of less than 5 kHz.

5. The method according to claim 4, further comprising essentially eliminating frequencies greater than 24 kHz are using the low-pass filter connected downstream.

6. The method according to claim 1, wherein the oscillation time signals are detected during at least one measurement travel of the carriage at a known velocity and known load.

7. The method according to claim 6, wherein the measurement travel is performed within 3 seconds.

8. The method according to claim 1, wherein the sensor device is fastened on the carriage normal with respect to a movement plane of the carriage.

9. The method according to claim 1, wherein the sensor device is arranged parallel and transverse to a movement direction with respect to a movement plane.

10. The method according to claim 1, wherein the sensor device has a piezoelectric sensor or a sensor fabricated using microsystem technology.
